(19) United States
(12) Patent Application Publication
(10) Pub. No.: US 2004/0196632 A1
(43) Pub. Date: Oct. 7, 2004

(54) Heat dissipation module

(76) Inventors: Chin-ming Chen, Taoyuan (TW); Li-kuang Tan, Taoyuan (TW); Yu-hung Huang, Ilan (TW)

Correspondence Address: MARTINE & PENILLA, LLP, 710 LAKEWAY DRIVE, SUITE 170, SUNNYVALE, CA, 94085, US

(21) Appl. No.: 10/712,708

(22) Filed: Nov. 12, 2003

(30) Foreign Application Priority Data
Apr. 1, 2003 (TW) 92205168

(51) Int. Cl. H05K 7/20

(52) U.S. Cl. 361/697; 165/121

(57) ABSTRACT

A heat dissipation module includes a fan and a heat sink. The shaft of the fan, made from materials with high thermal conductivity, has a first end and an opposite second end, with the first end penetrating a fan hub and connecting to a heating element. The heat sink is connected to the second end of the shaft.

### BACKGROUND OF THE INVENTION

1. Field of the Invention

The present invention relates to a heat dissipation module and, more particularly, to a heat dissipation module that modifies a fan structure to improve heat dissipation.

2. Description of the Related Art

Nowadays, as the capability of an electronic device is increased, a more capable heat dissipation module that works with the electronic device is needed.

FIG. 1 is a schematic view showing a heat dissipation device 100 installed on a heating element such as a CPU (not shown). The heat dissipation device 100 includes a heat sink 102 and an axial flow fan 104. After the heat sink 102 absorbs heat generated by the heating element through heat conduction, the airflow induced by the axial flow fan 104 can dissipate the heat absorbed by the heat sink 102.

However, as shown in FIG. 1, the conventional way that the fan 104 cooperates with the heat sink 102 in dissipating heat fails to promptly dissipate the heat absorbed by the heat sink 102, and the heat sink 102, therefore, is formed as another heat source above the heating element, thus impeding further improvement of the heat dissipation. Further, in order to dissipate a large amount of heat within a limited space, a design focused on enlarging areas of a heat sink is not an effective way since the space taken up by the heat sink goes up substantially.

### BRIEF SUMMARY OF THE INVENTION

In view of this, the object of this invention is to provide a heat dissipation module that can not only make inherent components of a fan structure assist in heat dissipation, but also improve the efficiency when a fan structure cooperates with a heat sink in dissipating heat.

In accordance with the invention, a heat dissipation module including a fan and a heat sink is provided. The shaft of the fan, made from materials with high thermal conductivity, has a first end and an opposite second end, with the first end penetrating a fan hub and connecting to a heating element and the second end connecting to the heat sink.

Through the design of the invention, since the shaft of the fan is made from materials with high thermal conductivity such as a heat pipe, the shaft can become a pivot of the entire heat dissipation mechanism and thus swiftly transfer the heat from the heating element to an forced-convection flow area above the rotor where the heat sink is just situated. Thus, the heat absorbed by the heat sink is swiftly removed, and high heat dissipation within a limited space can be easily accomplished.

### BRIEF DESCRIPTION OF THE DRAWINGS

FIG. 1 is a schematic view showing a conventional heat dissipation device.

FIG. 2 is an exploded view showing major components of a heat dissipation module according to an embodiment of the invention.

FIG. 3 is a cross-sectional view of the heat dissipation module shown in FIG. 2.

FIG. 4 is an exploded view showing major components of a heat dissipation module according to another embodiment of the invention.

FIG. 5 is a cross-sectional view of the heat dissipation module shown in FIG. 4.

### DETAILED DESCRIPTION OF THE INVENTION

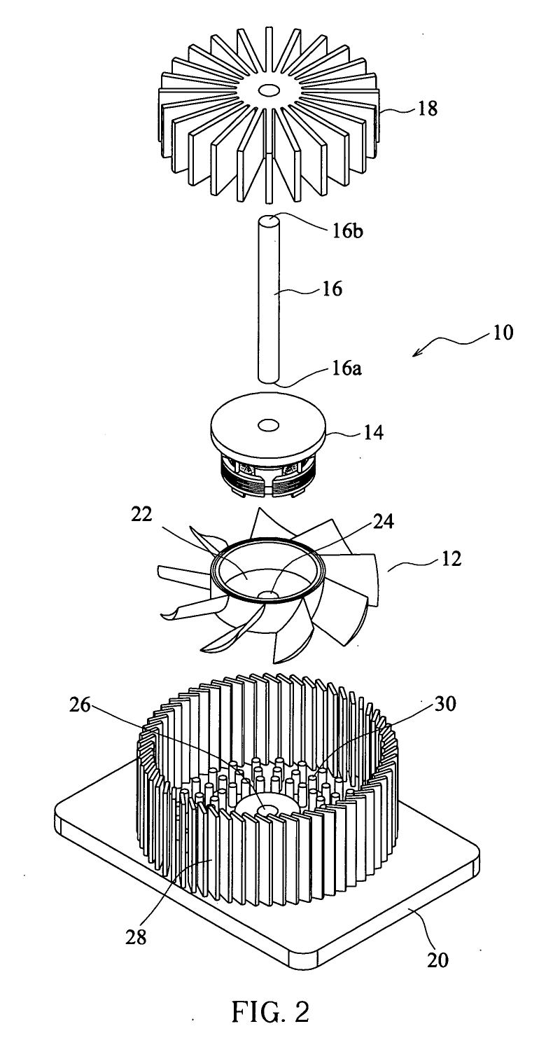

Referring to FIG. 2, there is shown an embodiment of a heat-dissipation module 10, which includes a rotor 12, stator assembly 14, heat pipe 16, heat sink 18 and base 20.

The interior edge of a hub 22 of the rotor 12 is adhered with a permanent magnet, and an opening 24 is formed in the central location of the hub 14. The stator assembly 14, composed of a circuit board, a coil and a silicon-steel plate, activates the rotor 12 through magnetic excitation.

The base 20 made from materials with high thermal conductivity is formed with a hole 26 in its central location where one end 16a of the heat pipe 16 can be fit. A plurality of teeth 28 circularly arranged on the base 20 are served as a fan frame to protect the rotor 12. A clearance, formed between each two adjacent teeth 28, functions as an extra air inlet for the side airflow so as to increase air flow volume. The shape, allocation and number of the teeth 28 may be optimized according to the flow field; for example, it may be optimized to conform to a flow channel design. Furthermore, a plurality of bumps 30 made from materials with high thermal conductivity can also be formed on the base 20.

The heat sink 18 can be any shape, and the way it is connected to the heat pipe 16 is not restricted. For example, the heat sink 18 may be formed with an opening thereon where one end 16b of the heat pipe 16 is inserted, while the other end 16a contacts the base 20.

According to this embodiment, to assemble the heat dissipation module 10, firstly, the stator assembly 14 is fixed on the heat pipe 16, and then the rotor 12 is fit onto the heat pipe 16 through an opening 24 located in the central location of the hub 22. That is, the heat pipe 16 is used to pivotally join the rotor 12 and the stator assembly 14, and thus served as a shaft of a fan structure. After that, the end 16a of the heat pipe 16 penetrating the hub 22 is inserted into the hole 26 of the base 20 so as to fix the heat pipe 16 on the base 20. The other end 16b of the heat pipe 16 is fit into the heat sink 18. Through the magnetic interaction, the rotor 12, when turning, can keep an appropriate float distance from the stator assembly 14 above the heat pipe 16 (i.e. the shaft).

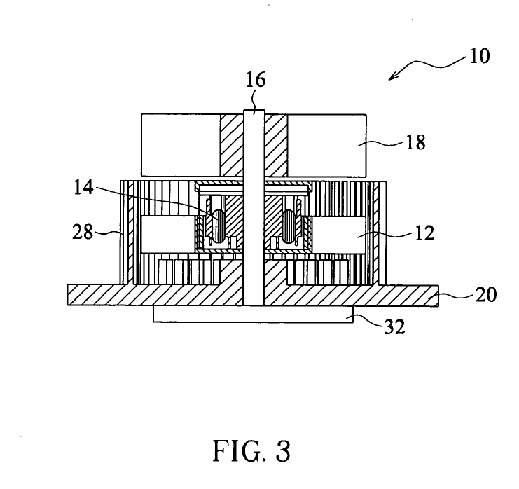

FIG. 3 is a cross-sectional view showing the assembled heat dissipation module 10. Referring to FIG. 3, when the base 20 is stuck on a heating element such as a CPU 32, because one end of the heat pipe 16 is fixed on the base 20 and the other end is fit into the heat sink 18, heat can be swiftly transferred from the CPU 32 to the heat sink 18 through the heat pipe 16. At the same time, since the heat pipe 16, i.e. the shaft, locates between the heat sink 18 and CPU 32, the airflow generated by the turning rotor 12 can swiftly remove the heat absorbed by the heat sink 18.

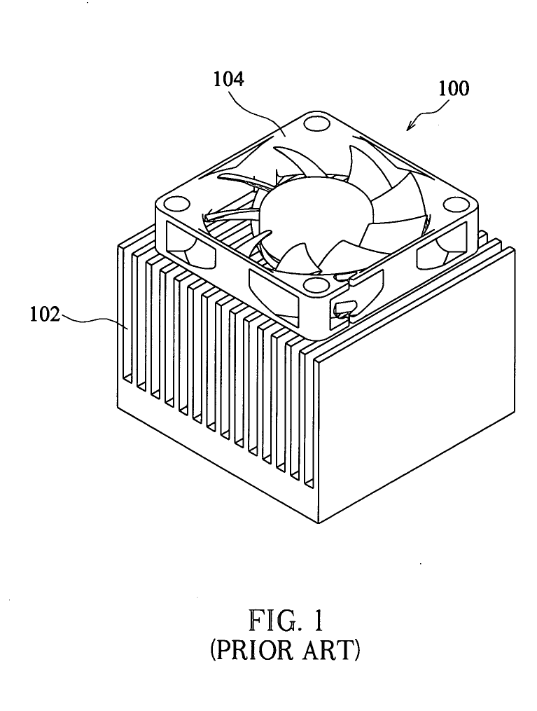

According to the invention, the heat pipe 16 is designed as a fan shaft, thus changing the essential design of a conventional fan structure to improve the heat dissipation. In other words, such design can not only make inherent components of a fan structure assist in heat dissipation, but also, when the fan structure cooperates with the heat sink in dissipating heat, improve the efficiency. Specifically, referring to the conventional cooperation between the fan and the heat sink shown in FIG. 1, after the heat sink 102 swiftly absorbs a great amount of heat, it is difficult for the fan 100 to promptly dissipate heat stored in the heat sink 102. Thus, the potential heat resistance between the heating element and the fan raises, hence impeding further improvement of the heat dissipation. However, through the design of the invention, the heat pipe 16 (i.e. the shaft), the pivot of the entire heat dissipation mechanism, can swiftly transfer heat from the heating element to an forced-convection flow area above the rotor 12 where the heat sink 18 is just situated. Thus, the heat absorbed by the heat sink 18 is swiftly removed, and high heat dissipation within a limited space is accomplished.

Moreover, through this design, the teeth 28 may also be made from materials with high thermal conductivity. Thereby, once the teeth 28 are arranged according to the air flow path, they are served as not only a fan frame but a heat sink. When both ends of the fan shaft connect to the heat sink 18 and the base 20, respectively, a multi-stage heat dissipation module with a heat pipe 16 accommodated therein is formed.

The fan shaft of this invention is including, but not limited to a heat pipe, and any materials with high thermal conductivity molded as a shaft can also be utilized. For instance, the above-mentioned materials with high thermal conductivity can be aluminum, copper, aluminum alloy, copper alloy or their compounds. In addition, when the heat dissipation module of the invention includes a base interposed between the shaft and the heating element, the shaft may be fixed on the base to connect to the heating element, and the heat generated by the heating element is dissipated after conducted to the base. The shaft, of course, may penetrate the base and touch the heating element.

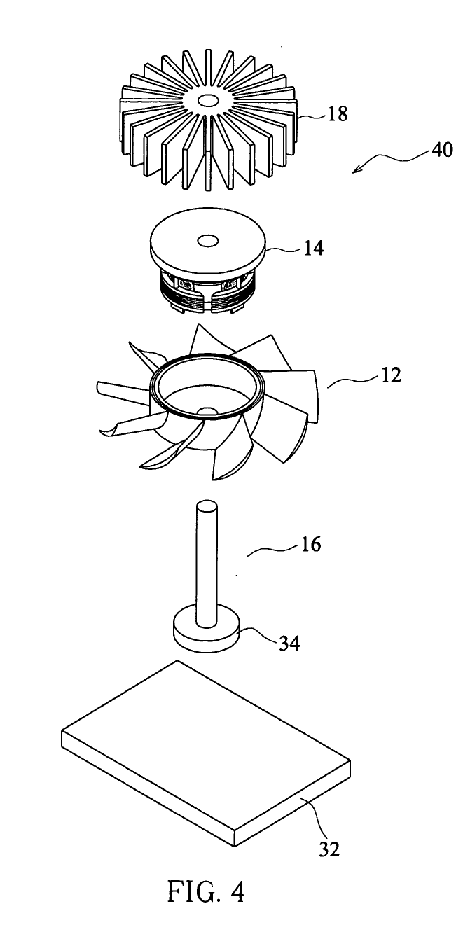

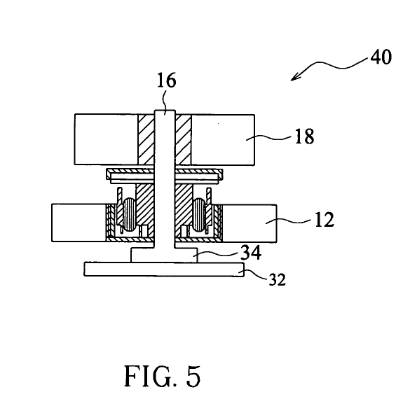

Referring to FIG. 4 and FIG. 5, there is shown another embodiment according to the invention. In the embodiment, after the stator assembly 14, the heat pipe 16 and the heat sink 18 are joined together, such assembled structure is directly connected to a heating element such as a CPU 32. The method for the connection of the heat pipe 16 and the heating element is not restricted. For instance, an enlarged portion 34 can be formed at one end of the heat pipe 16 to increase the area in contact with the heating element so as to facilitate the adherence and heat conduction between the heat pipe 16 and the heating element.

According to the invention, the design of the fan shaft adopts materials with high thermal conductivity such as a heat pipe 16, thus making inherent components of the fan structure assist in heat dissipation. For example, when a fan shaft adopts a heat pipe 16, it is also possible for the rotor 12 to adopt materials with high thermal conductivity and low specific weight such as aluminum alloy. Thereby, heat generated from the heating element can be transferred to the rotor 12 through the shaft (i.e. the heat pipe 16), and the rotor 12 can be made to function as a heat sink. Also, the high rotational speed of the rotor 12 can facilitate excellent heat dissipation. The rotor 12 and the heat sink 18 that are both made from materials with high thermal conductivity also form a multi-stage heat dissipation module with a heat pipe 16 accommodated therein, further improving the heat dissipation.

While the invention has been described by way of example and in terms of the preferred embodiment, it is to be understood that the invention is not limited to the disclosed embodiments. To the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A heat dissipation module, comprising:
a fan having a shaft with a first end and an opposite second end, the first end of the shaft penetrating a hub of the fan and connecting to a heating element; and
a heat sink connected to the second end of the shaft; wherein the shaft is made form materials with high thermal conductivity.

2. The heat dissipation module according to claim 1, wherein the shaft is a heat pipe.

3. The heat dissipation module according to claim 1, wherein the materials with high thermal conductivity is selected from the group of aluminum, copper, aluminum alloy, copper alloy and their compounds.

4. The heat dissipation module according to claim 1, further comprising a base mounted on the heating element, and the shaft is fixed on the base to connect to the heating element.

5. The heat dissipation module according to claim 4, wherein the base is formed with a plurality of teeth circularly arranged on its surface, and a gap is formed between two adjacent teeth.

6. The heat dissipation module according to claim 5, wherein the teeth are made from materials with high thermal conductivity.

7. The heat dissipation module according to claim 4, wherein the base is formed with a plurality of bumps on its surface.

8. The heat dissipation module according to claim 7, wherein the bumps are made from materials with high thermal conductivity.

9. The heat dissipation module according to claim 4, wherein the base is formed with an opening, and the shaft is inserted into the opening to fix on the base.

10. A heat dissipation module, comprising:
a shaft made from materials with high thermal conductivity having a first end connecting to a heating element and an opposite second end;
a stator assembly fixed on the shaft;
a rotor pivotally joined to the shaft and kept a fixed distance from the stator assembly through magnetic interaction; and
a heat sink connected to the second end.

11. The heat dissipation module according to claim 10, wherein the shaft is a heat pipe.

12. The heat dissipation module according to claim 10, wherein the materials with high thermal conductivity is selected from the group of aluminum, copper, aluminum alloy, copper alloy and their compounds.

13. The heat dissipation module according to claim 10, wherein the rotor is made from materials with high thermal conductivity.

14. The heat dissipation module according to claim 10, wherein the first end of the shaft is formed with an enlarged portion to increase an area in contact with the heating element.

15. The heat dissipation module according to claim 10, further comprising a base mounted on the heating element.

16. The heat dissipation module according to claim 15, wherein the base is interposed between the shaft and the heating element, and the shaft is fixed on the base to connect to the heating element.

17. The heat dissipation module according to claim 15, wherein the shaft penetrates the base and touches the heating element.

18. The heat dissipation module according to claim 15, wherein the base is formed with a plurality of teeth circularly arranged on its surface, and a gap is formed between two adjacent teeth.

19. The heat dissipation module according to claim 18, wherein the shape of the teeth conforms to a flow channel design.

20. The heat dissipation module according to claim 15, wherein the base is formed with a plurality of bumps on its surface.
